(19) United States
(12) Patent Application Publication
(10) Pub. No.: US 2022/0390918 A1
(43) Pub. Date: Dec. 8, 2022

(54) METHODS AND SYSTEMS FOR SELECTION OF MANUFACTURING ORIENTATION USING MACHINE LEARNING

(71) Applicant: PROTOLABS, INC., Maple Plain, MN (US)

(72) Inventor: Stefan Emilov Atev, Bethesda, MD (US)

(73) Assignee: PROTOLABS, INC., MAPLE PLAIN, MN (US)

(21) Appl. No.: 17/340,352

(22) Filed: Jun. 7, 2021

(51) Int. Cl. G05B 19/19; G06N 20/00; G06N 5/04; G05B 19/4097; G05B 13/02

(52) U.S. Cl. CPC G05B 19/19; G06N 20/00; G06N 5/04; G05B 19/4097; G05B 13/0265; G05B 2219/35134; G05B 2219/35167

(57) ABSTRACT

Aspects relate to methods and systems for manufacturing orientation selection, using machine learning. An exemplary method includes receiving, using a computing device, a computer model representative of a part for manufacture, inputting, using the computing device, the computer model to a machine learning model, determining, using the computing device, a plurality of candidate orientations as a function of the machine learning model and the computer model, and ranking, using the computing device, each candidate orientation of the plurality of candidate orientations as a function of the machine learning model and the computer model.

### FIELD OF THE INVENTION

The present invention generally relates to the field of Artificial Intelligence (AI), simulation, and modeling. In particular, the present invention is directed to selection of manufacturing orientation using machine learning.

### BACKGROUND

Orientation of a part being manufactured plays a critical role in ease and ability of manufacturing. Specifically, part orientation of a machined part may preclude formation of certain features, as tool access is occluded. However, it is not always obvious which part orientation is superior at the outset of manufacturing.

### SUMMARY OF THE DISCLOSURE

In an aspect a method of manufacturing orientation selection, using machine learning, includes receiving, using a computing device, a computer model representative of a part for manufacture, inputting, using the computing device, the computer model to a machine learning model, determining, using the computing device, a plurality of candidate orientations as a function of the machine learning model and the computer model, and ranking, using the computing device, each candidate orientation of the plurality of candidate orientations as a function of the machine learning model and the computer model.

In another aspect a system for manufacturing orientation selection, using machine learning, includes a computing device configured to receive a computer model representative of a part for manufacture input the computer model to a machine learning model, determine a plurality of candidate orientations as a function of the machine learning model and the computer model, and rank each candidate orientation of the plurality of candidate orientations as a function of the machine learning model and the computer model.

These and other aspects and features of non-limiting embodiments of the present invention will become apparent to those skilled in the art upon review of the following description of specific non-limiting embodiments of the invention in conjunction with the accompanying drawings.

### BRIEF DESCRIPTION OF THE DRAWINGS

For the purpose of illustrating the invention, the drawings show aspects of one or more embodiments of the invention. However, it should be understood that the present invention is not limited to the precise arrangements and instrumentalities shown in the drawings, wherein:

FIG. 1 is a block diagram illustrating an exemplary system for selection of manufacturing orientation;

FIG. 2 is a block diagram illustrating an exemplary system for training a machine learning model for selection of manufacturing orientation;

FIG. 3 is a block diagram illustrating an exemplary machine-learning process;

FIG. 4 is a flow diagram illustrating an exemplary method of selection of manufacturing orientation; and

FIG. 5 is a block diagram of a computing system that can be used to implement any one or more of the methodologies disclosed herein and any one or more portions thereof.

The drawings are not necessarily to scale and may be illustrated by phantom lines, diagrammatic representations and fragmentary views. In certain instances, details that are not necessary for an understanding of the embodiments or that render other details difficult to perceive may have been omitted.

### DETAILED DESCRIPTION

At a high level, aspects of the present disclosure are directed to systems and methods for selection of manufacturing orientation using machine learning. In an embodiment, candidate orientations are generated and ranked using a machine learning model. In some cases, this is advantageous as conventional methods of manufacturing orientation are either fraught with uncertainty or prohibitively computationally expensive. For example, in some cases, manufacturing orientation may be selected based upon at least a scoring function. Scoring function may be hand-designed and include practical heuristics. However, use of a scoring function does not ensure a best possible manufacturing orientation is selected. Instead, in some cases, every possible orientation may be used to generate a toolpath, for example by using a computer-aided manufacturing resource. In some cases, like that of 3 axis computer numeric controlled (CNC) milling, approximately 6 discrete manufacturing side setups, corresponding to the six faces of a cube, may be considered based upon a selected orientation. In some cases, depending upon part complexity between about 5 and about 100 candidate orientations may be considered, each of which may have 6 or more corresponding cardinal side setups. Depending on part geometry more or fewer discrete manufacturing orientations may need to be considered. In an exemplary case, 30 candidate orientations may be considered, a toolpath may be generated for each of the 30 candidate orientations and a best toolpath solution could be selected, for example based upon a manufacturing metric, such as manufacturing time. However, generating toolpaths is computationally expensive and in many cases, generating multiple toolpaths is prohibitively expensive.

Aspects of the present disclosure can be used to select a manufacturing orientation from a ranked list of candidate orientations, without needing to generate a toolpath for each orientation. Aspects of the present disclosure can also be used to generate a ranked list of candidate orientations based upon a machine learning model and a computer model. Additional aspects of the present disclosure may be used to train a machine learning model based upon generated toolpaths and sample computer models. This is so, at least in part, because generating of multiple orientation-variable toolpaths may be performed only during a training phase to limit computational expenses.

Aspects of the present disclosure allow for fast, efficient, and accurate selection of manufacturing orientation for a part being manufactured. Exemplary embodiments illustrating aspects of the present disclosure are described below in the context of several specific examples.

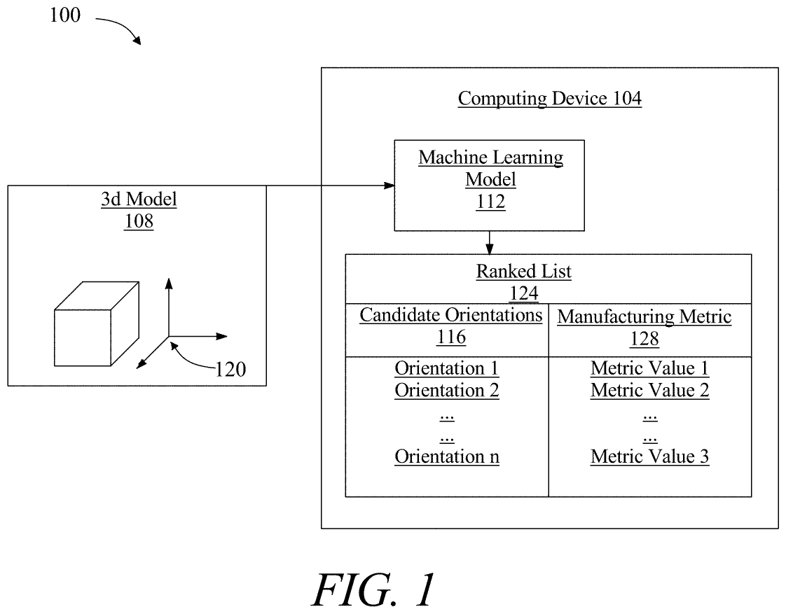

Referring now to FIG. 1, an exemplary embodiment of a system 100 manufacturing orientation selection using machine learning is illustrated. System includes a computing device 104. Computing device 104 may include any computing device as described in this disclosure, including without limitation a microcontroller, microprocessor, digital signal processor (DSP) and/or system on a chip (SoC) as described in this disclosure. Computing device may include, be included in, and/or communicate with a mobile device such as a mobile telephone or smartphone. Computing device 104 may include a single computing device operating independently, or may include two or more computing device operating in concert, in parallel, sequentially or the like; two or more computing devices may be included together in a single computing device or in two or more computing devices. Computing device 104 may interface or communicate with one or more additional devices as described below in further detail via a network interface device. Network interface device may be utilized for connecting computing device 104 to one or more of a variety of networks, and one or more devices. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network may employ a wired and/or a wireless mode of communication. In general, any network topology may be used. Information (e.g., data, software etc.) may be communicated to and/or from a computer and/or a computing device. Computing device 104 may include but is not limited to, for example, a computing device or cluster of computing devices in a first location and a second computing device or cluster of computing devices in a second location. Computing device 104 may include one or more computing devices dedicated to data storage, security, distribution of traffic for load balancing, and the like. Computing device 104 may distribute one or more computing tasks as described below across a plurality of computing devices of computing device, which may operate in parallel, in series, redundantly, or in any other manner used for distribution of tasks or memory between computing devices. Computing device 104 may be implemented using a “shared nothing” architecture in which data is cached at the worker, in an embodiment, this may enable scalability of system 100 and/or computing device.

With continued reference to FIG. 1, computing device 104 may be designed and/or configured to perform any method, method step, or sequence of method steps in any embodiment described in this disclosure, in any order and with any degree of repetition. For instance, computing device 104 may be configured to perform a single step or sequence repeatedly until a desired or commanded outcome is achieved; repetition of a step or a sequence of steps may be performed iteratively and/or recursively using outputs of previous repetitions as inputs to subsequent repetitions, aggregating inputs and/or outputs of repetitions to produce an aggregate result, reduction or decrement of one or more variables such as global variables, and/or division of a larger processing task into a set of iteratively addressed smaller processing tasks. Computing device 104 may perform any step or sequence of steps as described in this disclosure in parallel, such as simultaneously and/or substantially simultaneously performing a step two or more times using two or more parallel threads, processor cores, or the like; division of tasks between parallel threads and/or processes may be performed according to any protocol suitable for division of tasks between iterations. Persons skilled in the art, upon reviewing the entirety of this disclosure, will be aware of various ways in which steps, sequences of steps, processing tasks, and/or data may be subdivided, shared, or otherwise dealt with using iteration, recursion, and/or parallel processing.

With continued reference to FIG. 1, computing device 104 may perform determinations, classification, and/or analysis steps, methods, processes, or the like as described in this disclosure using machine learning processes. A “machine learning process,” as used in this disclosure, is a process that automatedly uses a body of data known as “training data” and/or a “training set” to generate an algorithm that will be performed by a computing device/module to produce outputs given data provided as inputs; this is in contrast to a non-machine learning software program where the commands to be executed are determined in advance by a user and written in a programming language. Computing device 104 may be configured to receive a computer model 108. As used in this disclosure, a “computer model” is a virtual representation. A computer model may include a 3d model and/or one or more 2d models, such as without limitation, digital prints or drawings. A computer model 108 may include a digital model of a physical structure as created using computer-aided design (CAD) modeling software. For example and without limitation, computer-aided design (CAD) software may include SOLIDWORKS® software and/or CATIA software (available from Dassault Systèmes of Vélizy-Villacoublay, France), AUTOCAD® software and/or Fusion 360 software (available from Autodesk, Inc., San Rafael, Calif.), PTC Creo software (available from PTC, Inc., Boston, Mass.), Siemens NX software (available from Siemens PLM Software, Plano, Tex.) and MICROSTATION® software (available from Bentley Systems, Inc., Exton, Pa.), and the like. computer model 108 may include any modeling type, such as, without limitation, a wireframe, solid model and/or any combination thereof. The computer model may be saved in a computer file using any suitable file protocol, such as, without limitation, SolidWorks part file (.SLDPRT), several SolidWorks part files organized into a single assembly (.SLDASM), 3D assembly file supported by various mechanical design programs (.STP), graphics file saved in a 2D/3D vector format based on the Initial Graphics Exchange Specification (.IGS) and/or the like. The computer model further includes information about the geometry and/or other defining properties of the mechanical part's structure. computer model 108, in some cases, may include a triangulated surface (e.g., .STLfile). In some cases, computer model 108 may be representative of a part for manufacture. As used in this disclosure, a “part” is any physical object that is manufactured. A part may be designed for manufacture, for example by using computer-aided design software. Manufacture may include subtractive manufacturing method, including machining, milling, and/or turning. Alternatively or additionally, in some cases, manufacture may include additive manufacturing. Non-limiting additive manufacturing methods may include fused deposition manufacturing (FDM), selective laser melting (SLM), selective laser sintering (SLS), direct selective laser sintering (DSLM), multi-jet fusion (MJF), PolyJet, carbon digital light synthesis (DLS), continuous liquid interface production (CLIP), and the like.

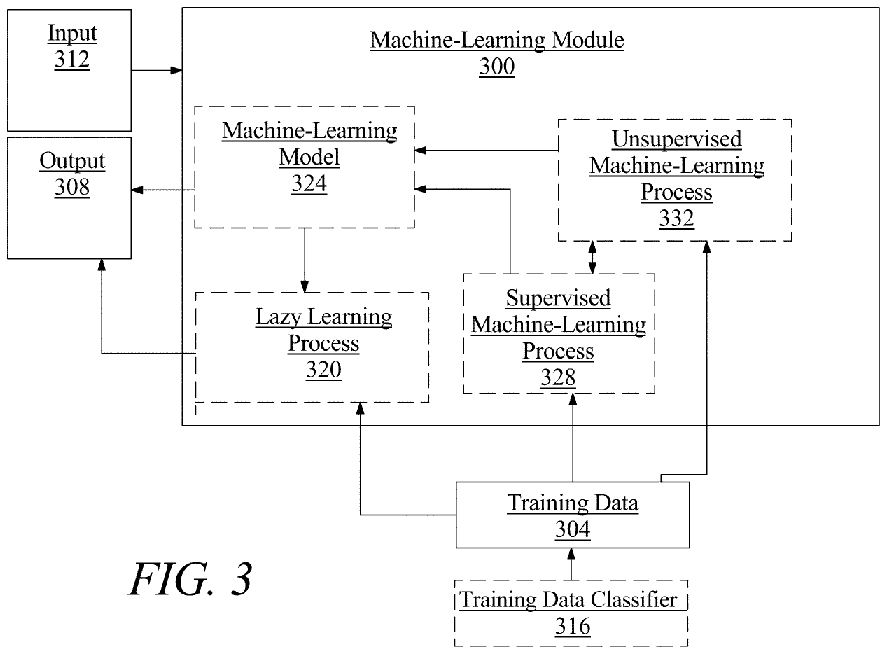

With continued reference to FIG. 1, computing device 104 may input computer model 108 to a machine learning model 112. Machine learning model may include any machine learning modeled described in this disclosure, for example below and with reference to FIGS. 3-5. In some embodiments, machine learning model may include a ranking model. A ranking model may be generated by any machine learning process including supervised machine learning algorithms, semi-supervised machine learning algorithms, and/or reinforcement machine learning algorithms. Computing device 104 may determine a plurality of candidate orientations 116 as a function of machine learning model 112 and computer model 108. In some cases, ranking candidate orientation 116 may include a learning to rank process. As used in this disclosure, “learning to rank” is an application of machine learning processes in generation and use of models for ranking. As used in this disclosure, an “orientation” is a direction relative a coordinate system. For example, in some cases, an orientation of a part for manufacture may be determined relative a coordinate system of a tool, on which the part may be manufactured. A computer model 108 may include a coordinate system 120. Orientation of a computer model 108, in some cases, may include orienting a tool's coordinate system with that of the computer model 108. A “tool” as used in this disclosure is any manufacturing device or system configured to manufacture a part.

With continued reference to FIG. 1, in some cases a learning to rank process may include “pairwise rank learning”. As used in this disclosure, “pairwise rank learning” is a learning to rank process that compares pairs of elements of training data. In some cases, pairwise rank learning may include a process that compares a plurality, such as without limitation every possible, pair combinations of a candidate orientations. Pairwise learning process may compare each pair combination to determine one of three possible outcomes for each pair. In an exemplary embodiment a first candidate orientation is paired and compared with a second candidate orientation. In this exemplary embodiment, three possible outcomes may include first orientation is WORSE, first candidate orientation is SAME, or first candidate orientation is BETTER when compared to second candidate orientation. Training of a pairwise rank learning process may include a training set included pair combinations of candidate orientations as well as their corresponding at least a manufacturing metric, which may be based upon computationally expensive toolpathing processes. In some cases, machine learning model 112 may be used to generate a so-called “weak partial order.” As used in this disclosure, a “weak partial order” of candidate orientations is a ranked enumeration of candidate orientations that are Pareto-optimal. As used in this disclosure, “Pareto-optimal” candidate orientations are candidate orientations that are never WORSE than any other candidate orientation, for example after pairwise comparison. In some cases, Pareto-optimal candidate orientations may all be considered equivalent by machine learning model 112. In some cases, a tie-breaking function may be employed to break a tie between two or more Pareto-optimal candidate orientations. In some cases, tie-breaking function may include a machine learning process or another process. For example, tie-breaking function may include a scoring metric for candidate orientations. Alternatively or additionally, tie-breaking function may include one or more other considerations, such as without limitation minimizing a thickness and/or volume of material needed to support part during manufacture in candidate orientation. In some cases, a machine learning model 112 may be used to score each candidate orientation before a pairwise ranking function is used, and the score for each candidate orientation is used in the pairwise ranking function; alternatively or additionally, in some cases, necessary scoring for comparing pairs of candidate orientations is performed by pairwise ranking function. In some cases, candidate orientations may first be filtered according to access for feature formation. In some cases, a plurality of candidate orientations are present wherein all features are accessible by machine tool for formation during manufacturing and machine learning model 112 may be used to select an optimal candidate orientation from this grouping. In some cases, a learning to rank process may be used in conjunction with a machine learning classifier, for example like those described below.

With continued reference to FIG. 1, computing device 104 may rank each candidate orientation of plurality of candidate orientations 120 as a function of machine learning model 112 and computer model 108. In some cases, computing device 104 may generate a ranked list 124 that includes a ranking of plurality of candidate orientations 120. In some cases, ranking candidate orientations 116 may be based upon a manufacturing metric 128. As used in this disclosure, a “manufacturing metric” is a quantifiable measure of a characteristic associated with manufacture. For example, a manufacturing metric may include, without limitation, manufacturing time, completeness of manufacture, material usage or waste, energy consumption, tool utilization, and the like. In some embodiments, ranking of candidate orientations may be based upon manufacturing time. As used in this disclosure, “manufacturing time” may include an amount of time for completion of a manufacturing step or operation. In some embodiments, ranking of candidate orientations may be based upon completeness of manufacturing. As used in this disclosure, “completeness of manufacture” is a quantifiable indication, for example proportionality, of similarity between a manufactured part and a complete part. For example, in some cases, complete manufacture of a part is not possible in one step or operation. For example, depending on orientation features of manufactured part may not be able to be formed. In this case, completeness of manufacture would quantifiably indicate how close the manufactured part is to a complete part.

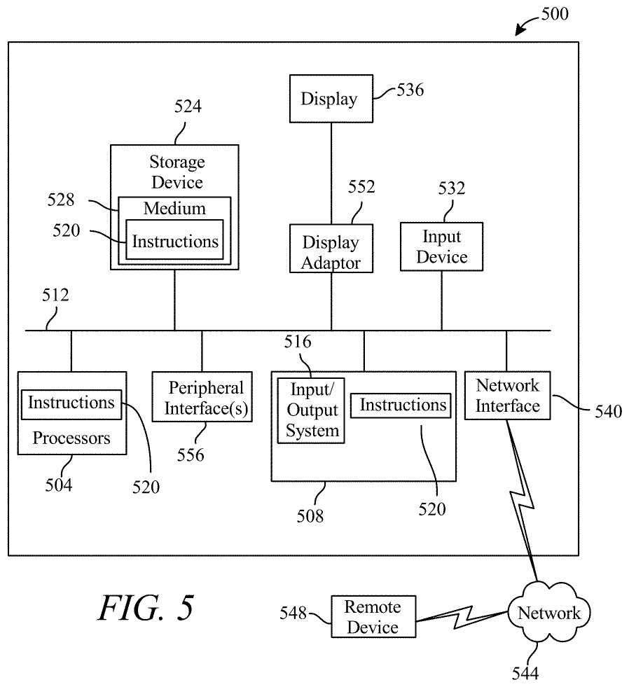

Still referring to FIG. 1, in some embodiments, computing device 104 may receive computer model from a user device. As used in this disclosure, a “user device” is any computing device used by a user. In some cases, user device may be remote and communicative with at least another computing device by way of at least a network. Exemplary non-limiting user devices include laptop computers, workstations, tablets, and smart phones. User device may include any computing device described in reference to FIG. 5. In some cases, computer model 108 may be received along with a request for quotation from user device. A “request for quotation” as used in this disclosure is an explicit or implicit solicitation for a price to manufacture a part. In some cases, a request for quotation may include a manufacturing request datum.

With continued reference to FIG. 1, system 100 may be configured to receive a manufacturing request datum from a user device. Manufacturing request datum may additionally include at least an element of user mechanical part data, for example computer model 108. Manufacturing request datum may include any data describing and/or relating to a request for manufacture of at least a part, for example a CNC machined part. “Request for manufacture,” as used in this disclosure, includes a buyer inviting a supplier to submit a bid on the buyer's specific manufacturing inquiry. A “bid,” as described in this disclosure, includes an estimated cost to manufacture the buyer's desired manufacturing inquiry. A request for manufacture may include, without limitation, a price quote, a price request, a quote request, a pricing enquiry, price prediction, and the like. A request for manufacture may further include, without limitation, a computer model 108 of a part considered for subtractive manufacture.

Still referring to FIG. 1, in some embodiments, computing device 104 may be additionally configured to receive an element of part data. As used in this disclosure, “part data” is information related to a part. Non-limiting examples of part data include quantity, material, requested lead time, surface finish, manufacturing process, and dimensional tolerance. In some cases, computing device 104 may select machine learning model 112 as a function of an element of part data or computer model 108. For example, in some cases, element of data may be used to determine an appropriate manufacturing process and a machine learning model will be selected based upon that manufacturing process; alternatively or additionally, training data may be selected based upon determination of an appropriate manufacturing process.

Continuing to refer to FIG. 1, manufacturing request datum may include at least an element of part data. Part data may include any descriptive attributes of manufacturing request datum. “Descriptive attributes,” as used in this disclosure, are any features, limitations, details, restrictions and/or specifications of manufacturing request datum. Descriptive attributes may include, without limitation, any features, limitations, details, restrictions and/or specifications relating to the CNC mechanical part geometry, materials, finishes, connections, hardware, special processes, dimensions, tolerances, and the like. Descriptive attributes may further include, without limitation, any features, limitations, details, restrictions, and/or specifications relating to a total request for manufacture, such as total amount of CNC mechanical parts, restrictions on deadline to have request completed, and the like. As an example and without limitation, part data may include part count data, i.e., quantity, that contains the total number of each part included in manufacturing request datum, such as without limitation a request to have a total number of 24 brackets manufactured. As a further example and without limitation, part data may include part face count data that contains a total number of faces on part included in manufacturing request datum, such as without limitation a price request to have a hollow box with a total of 10 faces manufactured. As another example and without limitation, part data may include part material data that contains material of part, such as without limitation a quote request for a steel roller bushing. Persons skilled in the art, upon reviewing the entirety of this disclosure, will be aware of various descriptive attributes which may be suitable for part data consistent with this disclosure.

Still referring to FIG. 1, in some embodiments, computing device 104 may input computer model 108 to a computer aided manufacturing resource. As used in this disclosure, “computer-aided manufacturing (CAM) resource” is a resource that generates manufacturing instructions for a tool based upon a computer model 108. For example, in some cases, a CAM resource may generate a toolpath based upon a computer model 108. Non-limiting exemplary CAM resources include GibbsCAM from GibbsCAM of Moorpark, Calif., U.S.A. and ESPRIT from DP Technology of Camarillo, Calif., U.S.A., MasterCAM from CNC Software inc. of Tolland, Conn., U.S.A., CAMWorks from HCL Technologies of Noida, India, SOLIDWORKS® CAM from Dassault Systèmes of Vélizy-Villacoublay, France, and the like. Additional disclosure related to automatic quoting and toolpath generation may be found in U.S. Pat. No. 8,140,401 entitled “AUTOMATED QUOTING OF MOLDS AND PARTS FRM CUSTOMER CAD FILE PART DATA,” by L. Lukis et al., incorporated herein by reference. In some cases, computing device 104 may generate a toolpath as a function of computer model 108, CAM resource, and a candidate orientation of plurality of candidate orientations 116. As used in this disclosure, a “toolpath” is a set of instructions required for a tool to manufacture a part. In some cases, a toolpath may literally include a toolpath or a set of directions for a tool, such as a cuter, to move in during manufacturing. For example, in some cases, a user may select an orientation from plurality of candidate orientations 116. Alternatively or additionally, in some cases, computing device 104 may automatically select a candidate orientation from plurality of candidate orientations, for example without limitation based upon ranked list 124. In some cases, computing device 104 may transmit toolpath to a tool, for example for manufacturing of a part based upon computer model 108. In some embodiments, computing device 104 may be communicative with tool by way of one or more networks, for example networks described in detail in reference to FIG. 5.

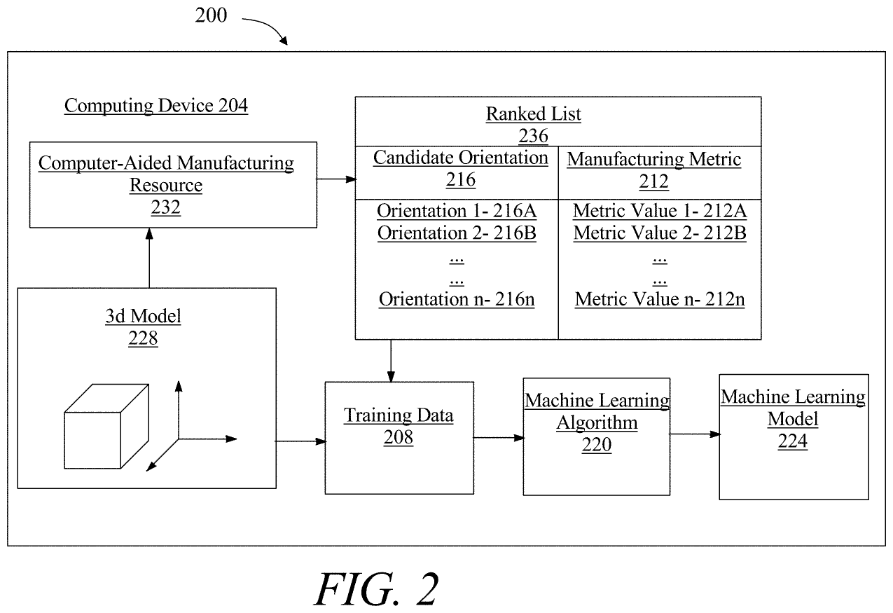

Referring now to FIG. 2, an exemplary system 200 for training a machine learning process and selecting a manufacturing orientation using said machine learning process is illustrated. System 200 may include a computing device 204. Computing device 204 may receive training data 208. Training data 208 may include data containing correlations that a machine-learning process may use to model relationships between two or more categories of data elements. For instance, and without limitation, training data may include a plurality of data entries, each entry representing a set of data elements that were recorded, received, and/or generated together; data elements may be correlated by shared existence in a given data entry, by proximity in a given data entry, or the like. Multiple data entries in training data may evince one or more trends in correlations between categories of data elements; for instance, and without limitation, a higher value of a first data element belonging to a first category of data element may tend to correlate to a higher value of a second data element belonging to a second category of data element, indicating a possible proportional or other mathematical relationship linking values belonging to the two categories. Multiple categories of data elements may be related in training data according to various correlations; correlations may indicate causative and/or predictive links between categories of data elements, which may be modeled as relationships such as mathematical relationships by machine-learning processes as described in further detail below. Training data may be formatted and/or organized by categories of data elements, for instance by associating data elements with one or more descriptors corresponding to categories of data elements. As a non-limiting example, training data may include data entered in standardized forms by persons or processes, such that entry of a given data element in a given field in a form may be mapped to one or more descriptors of categories. Elements in training data may be linked to descriptors of categories by tags, tokens, or other data elements; for instance, and without limitation, training data may be provided in fixed-length formats, formats linking positions of data to categories such as comma-separated value (CSV) formats and/or self-describing formats such as extensible markup language (XML), JavaScript Object Notation (JSON), or the like, enabling processes or devices to detect categories of data.

With continued reference to FIG. 2, alternatively or additionally, training data may include one or more elements that are not categorized; that is, training data may not be formatted or contain descriptors for some elements of data. Machine-learning algorithms and/or other processes may sort training data according to one or more categorizations using, for instance, natural language processing algorithms, tokenization, detection of correlated values in raw data and the like; categories may be generated using correlation and/or other processing algorithms. As a non-limiting example, in a corpus of text, phrases making up a number “n” of compound words, such as nouns modified by other nouns, may be identified according to a statistically significant prevalence of n-grams containing such words in a particular order; such an n-gram may be categorized as an element of language such as a “word” to be tracked similarly to single words, generating a new category as a result of statistical analysis. Similarly, in a data entry including some textual data, a person's name may be identified by reference to a list, dictionary, or other compendium of terms, permitting ad-hoc categorization by machine-learning algorithms, and/or automated association of data in the data entry with descriptors or into a given format. The ability to categorize data entries automatedly may enable the same training data to be made applicable for two or more distinct machine-learning algorithms as described in further detail below. Training data used by computing device 204 may correlate any input data as described in this disclosure to any output data as described in this disclosure. Training data 208, additionally, may include any training data described in this application, for example below. In some cases, training data 208 may correlate at least a manufacturing metric 212 to candidate orientations 216 for at least a sample part. Computing device 204 may input training data 208 to a machine learning algorithm 220. Machine learning algorithm may include any machine learning algorithm described in this disclosure, for example with reference to FIGS. 1 and 3-5. In some cases, training data may include at least a feature vector and machine learning algorithm may include a supervised machine learning algorithm. Computing device 204 may train machine learning model 224 as a function of the machine learning algorithm 220 and training data 208.

With continued reference to FIG. 2, computing device 204 may be additionally configured to generate training data 208. For instance in some embodiments, computing device 204 may input at least a sample computer model 228 representing at least a sample part, for example of a plurality of sample parts to a computer aided manufacturing (CAM) resource 232. Computing device 204 may generate a first toolpath as a function of sample computer model, CAM resource 232, and a first candidate orientation 216A. Computing device 204 may generate a second toolpath as a function of sample computer model 228, CAM resource 232, and a second candidate orientation 216B. Computing device 204 may determine at least a first manufacturing metric value 212A as a function of first toolpath and at least a second manufacturing metric 212B as a function of second toolpath. For example, in some cases, CAM resource 232 may be used to generate a predicted manufacturing time and/or a completeness of manufacture for each toolpath. In some embodiments, computing device 204 may generate a ranked list 236 of a plurality of candidate orientations 216, for example based upon a manufacturing metric 212. Computing device 204 may generate training data 208 correlating first candidate orientation 216A to first manufacturing metric value 212A and second candidate orientation 216B to at least a second manufacturing metric 212B. In some cases, CAM resource 232 will generate toolpaths specifically for machining toolpaths, for example cutting tools, such as without limitation drills, mills, cutters, broaches, boring bars, T-cutters, and the like. In some cases, machining toolpaths are generated specifically for machine tools. Exemplary machine tools include without limitation mills, lathes, screw machines, Swiss machines, live turning machines, multi-axis turning centers, and the like.

Still referring to FIG. 2, in some embodiments during use system 200 may retrain machine learning model 224, for example without limitation continuously and/or periodically. Referring briefly to FIG. 1, as described above a ranked list 124 is generated and ranked as a function of machine learning model 112 224. In some cases, a further selection process may be performed with ranked list 124. For example, in some cases a technician may review ranked list and manually select an orientation for manufacture from the ranked list 124. In some cases, another computer algorithm and/or machine learning process may be used to automatically select an orientation from ranked list 124. In some cases, a selected orientation (be it from manual or automatic processes) may be correlated to at least one of computer model 108, candidate orientations 116, and manufacturing metric 128 and used to generate further training data 208.

Still referring to FIG. 2, in some cases, machine learning model 224 may be evaluated. For example, performance of orientation selection using a machine learning model 224 may be comparatively evaluated for example against conventional scoring algorithms, manual orientation selection, and/or computationally exhaustive methods. As described above, a computationally exhaustive method for orientation selection, in some cases, may include generating a toolpath, using CAM software, for each of a multiple (e.g., 6 or more) orientations and selecting a preferred orientation as a function of the resulting toolpaths. In some cases, performance of orientation selection may be based upon at least manufacturing metric 212. In some cases, performance of orientation selection may be determined on a per unit (part) bases. Alternatively or additionally, in some cases, performance of orientation selection may be determined en masse, for example by way of aggregation, probabilistic, and/or statistically methods.

Referring now to FIG. 3, an exemplary embodiment of a machine-learning module 300 that may perform one or more machine-learning processes as described in this disclosure is illustrated. Machine-learning module may perform determinations, classification, and/or analysis steps, methods, processes, or the like as described in this disclosure using machine learning processes. A machine learning process may include a process that automatedly uses training data 304 to generate an algorithm that will be performed by a computing device/module to produce outputs 308 given data provided as inputs 312; this is in contrast to a non-machine learning software program where the commands to be executed are determined in advance by a user and written in a programming language.

Still referring to FIG. 3, training data may include data containing correlations that a machine-learning process may use to model relationships between two or more categories of data elements. For instance, and without limitation, training data 304 may include a plurality of data entries, each entry representing a set of data elements that were recorded, received, and/or generated together; data elements may be correlated by shared existence in a given data entry, by proximity in a given data entry, or the like. Multiple data entries in training data 304 may evince one or more trends in correlations between categories of data elements; for instance, and without limitation, a higher value of a first data element belonging to a first category of data element may tend to correlate to a higher value of a second data element belonging to a second category of data element, indicating a possible proportional or other mathematical relationship linking values belonging to the two categories. Multiple categories of data elements may be related in training data 304 according to various correlations; correlations may indicate causative and/or predictive links between categories of data elements, which may be modeled as relationships such as mathematical relationships by machine-learning processes as described in further detail below. Training data 304 may be formatted and/or organized by categories of data elements, for instance by associating data elements with one or more descriptors corresponding to categories of data elements. As a non-limiting example, training data 304 may include data entered in standardized forms by persons or processes, such that entry of a given data element in a given field in a form may be mapped to one or more descriptors of categories. Elements in training data 304 may be linked to descriptors of categories by tags, tokens, or other data elements; for instance, and without limitation, training data 304 may be provided in fixed-length formats, formats linking positions of data to categories such as comma-separated value (CSV) formats and/or self-describing formats such as extensible markup language (XML), JavaScript Object Notation (JSON), or the like, enabling processes or devices to detect categories of data.

Alternatively or additionally, and continuing to refer to FIG. 3, training data 304 may include one or more elements that are not categorized; that is, training data 304 may not be formatted or contain descriptors for some elements of data. Machine-learning algorithms and/or other processes may sort training data 304 according to one or more categorizations using, for instance, natural language processing algorithms, tokenization, detection of correlated values in raw data and the like; categories may be generated using correlation and/or other processing algorithms. As a non-limiting example, in a corpus of text, phrases making up a number “n” of compound words, such as nouns modified by other nouns, may be identified according to a statistically significant prevalence of n-grams containing such words in a particular order; such an n-gram may be categorized as an element of language such as a “word” to be tracked similarly to single words, generating a new category as a result of statistical analysis. Similarly, in a data entry including some textual data, a person's name may be identified by reference to a list, dictionary, or other compendium of terms, permitting ad-hoc categorization by machine-learning algorithms, and/or automated association of data in the data entry with descriptors or into a given format. The ability to categorize data entries automatedly may enable the same training data 304 to be made applicable for two or more distinct machine-learning algorithms as described in further detail below. Training data 304 used by machine-learning module 300 may correlate any input data as described in this disclosure to any output data as described in this disclosure. As a non-limiting illustrative example inputs may include computer models 228 correlated to outputs, which may include ranked lists 236 of orientations by at least a manufacturing metric 212, as described in reference to FIG. 2.

Further referring to FIG. 3, training data may be filtered, sorted, and/or selected using one or more supervised and/or unsupervised machine-learning processes and/or models as described in further detail below; such models may include without limitation a training data classifier 316. Training data classifier 316 may include a “classifier,” which as used in this disclosure is a machine-learning model as defined below, such as a mathematical model, neural net, or program generated by a machine learning algorithm known as a “classification algorithm,” as described in further detail below, that sorts inputs into categories or bins of data, outputting the categories or bins of data and/or labels associated therewith. A classifier may be configured to output at least a datum that labels or otherwise identifies a set of data that are clustered together, found to be close under a distance metric as described below, or the like. Machine-learning module 300 may generate a classifier using a classification algorithm, defined as a processes whereby a computing device and/or any module and/or component operating thereon derives a classifier from training data 304. Classification may be performed using, without limitation, linear classifiers such as without limitation logistic regression and/or naive Bayes classifiers, nearest neighbor classifiers such as k-nearest neighbors classifiers, support vector machines, least squares support vector machines, fisher's linear discriminant, quadratic classifiers, decision trees, boosted trees, random forest classifiers, learning vector quantization, and/or neural network-based classifiers. As a non-limiting example, training data classifier 316 may classify elements of training data as a function of part data and/or attributes of computer model. For example, a computer model may represent a generally cylindrical part that is most appropriate for a turning process. In some cases, it may be most appropriate to classify training data associated with turned parts compared to machined parts. Likewise, materials machined from harder metals, such as Steel, may not be adequately considered using a machine learning model trained using parts to be machined from soft metals, such as Aluminum, and/or plastics. In some cases, therefore training data may be classified according to material part data.

Still referring to FIG. 3, machine-learning module 300 may be configured to perform a lazy-learning process 320 and/or protocol, which may alternatively be referred to as a “lazy loading” or “call-when-needed” process and/or protocol, may be a process whereby machine learning is conducted upon receipt of an input to be converted to an output, by combining the input and training set to derive the algorithm to be used to produce the output on demand. For instance, an initial set of simulations may be performed to cover an initial heuristic and/or “first guess” at an output and/or relationship. As a non-limiting example, an initial heuristic may include a ranking of associations between inputs and elements of training data 304. Heuristic may include selecting some number of highest-ranking associations and/or training data 304 elements. Lazy learning may implement any suitable lazy learning algorithm, including without limitation a K-nearest neighbors algorithm, a lazy naïve Bayes algorithm, or the like; persons skilled in the art, upon reviewing the entirety of this disclosure, will be aware of various lazy-learning algorithms that may be applied to generate outputs as described in this disclosure, including without limitation lazy learning applications of machine-learning algorithms as described in further detail below.

Alternatively or additionally, and with continued reference to FIG. 3, machine-learning processes as described in this disclosure may be used to generate machine-learning models 324. A “machine-learning model,” as used in this disclosure, is a mathematical and/or algorithmic representation of a relationship between inputs and outputs, as generated using any machine-learning process including without limitation any process as described above and stored in memory; an input is submitted to a machine-learning model 324 once created, which generates an output based on the relationship that was derived. For instance, and without limitation, a linear regression model, generated using a linear regression algorithm, may compute a linear combination of input data using coefficients derived during machine-learning processes to calculate an output datum. As a further non-limiting example, a machine-learning model 324 may be generated by creating an artificial neural network, such as a convolutional neural network comprising an input layer of nodes, one or more intermediate layers, and an output layer of nodes. Connections between nodes may be created via the process of “training” the network, in which elements from a training data 304 set are applied to the input nodes, a suitable training algorithm (such as Levenberg-Marquardt, conjugate gradient, simulated annealing, or other algorithms) is then used to adjust the connections and weights between nodes in adjacent layers of the neural network to produce the desired values at the output nodes. This process is sometimes referred to as deep learning.

Still referring to FIG. 3, machine-learning algorithms may include at least a supervised machine-learning process 328. At least a supervised machine-learning process 328, as defined herein, include algorithms that receive a training set relating a number of inputs to a number of outputs, and seek to find one or more mathematical relations relating inputs to outputs, where each of the one or more mathematical relations is optimal according to some criterion specified to the algorithm using some scoring function. For instance, a supervised learning algorithm may include computer models representing sample parts as described above as inputs, ranked lists of orientations and associated manufacturing metrics generated through computational expensive means as outputs, and a scoring function representing a desired form of relationship to be detected between inputs and outputs; scoring function may, for instance, seek to maximize the probability that a given input and/or combination of elements inputs is associated with a given output to minimize the probability that a given input is not associated with a given output. Scoring function may be expressed as a risk function representing an “expected loss” of an algorithm relating inputs to outputs, where loss is computed as an error function representing a degree to which a prediction generated by the relation is incorrect when compared to a given input-output pair provided in training data 304. Persons skilled in the art, upon reviewing the entirety of this disclosure, will be aware of various possible variations of at least a supervised machine-learning process 328 that may be used to determine relation between inputs and outputs. Supervised machine-learning processes may include classification algorithms as defined above.

Further referring to FIG. 3, machine learning processes may include at least an unsupervised machine-learning processes 332. An unsupervised machine-learning process, as used herein, is a process that derives inferences in datasets without regard to labels; as a result, an unsupervised machine-learning process may be free to discover any structure, relationship, and/or correlation provided in the data. Unsupervised processes may not require a response variable; unsupervised processes may be used to find interesting patterns and/or inferences between variables, to determine a degree of correlation between two or more variables, or the like.

Still referring to FIG. 3, machine-learning module 300 may be designed and configured to create a machine-learning model 324 using techniques for development of linear regression models. Linear regression models may include ordinary least squares regression, which aims to minimize the square of the difference between predicted outcomes and actual outcomes according to an appropriate norm for measuring such a difference (e.g. a vector-space distance norm); coefficients of the resulting linear equation may be modified to improve minimization. Linear regression models may include ridge regression methods, where the function to be minimized includes the least-squares function plus term multiplying the square of each coefficient by a scalar amount to penalize large coefficients. Linear regression models may include least absolute shrinkage and selection operator (LASSO) models, in which ridge regression is combined with multiplying the least-squares term by a factor of 1 divided by double the number of samples. Linear regression models may include a multi-task lasso model wherein the norm applied in the least-squares term of the lasso model is the Frobenius norm amounting to the square root of the sum of squares of all terms. Linear regression models may include the elastic net model, a multi-task elastic net model, a least angle regression model, a LARS lasso model, an orthogonal matching pursuit model, a Bayesian regression model, a logistic regression model, a stochastic gradient descent model, a perceptron model, a passive aggressive algorithm, a robustness regression model, a Huber regression model, or any other suitable model that may occur to persons skilled in the art upon reviewing the entirety of this disclosure. Linear regression models may be generalized in an embodiment to polynomial regression models, whereby a polynomial equation (e.g. a quadratic, cubic or higher-order equation) providing a best predicted output/actual output fit is sought; similar methods to those described above may be applied to minimize error functions, as will be apparent to persons skilled in the art upon reviewing the entirety of this disclosure.

Continuing to refer to FIG. 3, machine-learning algorithms may include, without limitation, linear discriminant analysis. Machine-learning algorithm may include quadratic discriminate analysis. Machine-learning algorithms may include kernel ridge regression. Machine-learning algorithms may include support vector machines, including without limitation support vector classification-based regression processes. Machine-learning algorithms may include stochastic gradient descent algorithms, including classification and regression algorithms based on stochastic gradient descent. Machine-learning algorithms may include nearest neighbors algorithms. Machine-learning algorithms may include Gaussian processes such as Gaussian Process Regression. Machine-learning algorithms may include cross-decomposition algorithms, including partial least squares and/or canonical correlation analysis. Machine-learning algorithms may include naïve Bayes methods. Machine-learning algorithms may include algorithms based on decision trees, such as decision tree classification or regression algorithms. Machine-learning algorithms may include ensemble methods such as bagging meta-estimator, forest of randomized tress, AdaBoost, gradient tree boosting, and/or voting classifier methods. Machine-learning algorithms may include neural net algorithms, including convolutional neural net processes.

Continuing with reference to FIG. 3, in some cases, machine learning model 324 may include a ranking model. A ranking model may include any machine learning model described in this disclosure; and a ranking model may be generated and/or trained using any machine learning algorithm or process described in this disclosure. In some cases, a ranking model can be broadly divided into three types: Boolean models, Vector Space Models, and Probabilistic Models. Boolean Model may be a simple baseline model following underlying principles of relational algebra with algebraic expressions and where orientations are not generated unless they completely match, for example according to a manufacturing metric. A Vector Space Model may include vectors representative of computer model and/or part data features. Vectors may be assigned with weights. Weights may be ranged from positive (if matched completely to an orientation based upon some metric) to negative (if unmatched or completely oppositely matched). A similarity score between a computer model and/or an element of part data and an orientation can be found by calculating a cosine value between an input weight vector and an output weight vector using cosine similarity. Orientation can be generated and ranked according to similarity score and generated top k orientations which have highest scores or are most relevant to an input (computer model and/or part data) vector. In probabilistic model, probability theory may be used as a principal means for modeling manufacturing metrics based upon orientation in mathematical terms. Probabilistic model applies a theory of probability to ranking (an event has a possibility from 0 percent to 100 percent of occurring). For example, in some cases, a manufacturing metric may include a probabilistic term. Orientations may therefore be ranked in decreasing probability, for example probability of being a preferred orientation. Probability models, therefore, in some cases may be used to consider uncertainty in orientation selection process. In some cases, a probability model may estimate and calculate a probability that an orientation will be desired given an input, for example a computer model and/or part data. In some cases, a probability model may rank orientation along a continuum without, for example direct reference to manufacturing metrics, such as time of manufacture and/or completeness of manufacture.

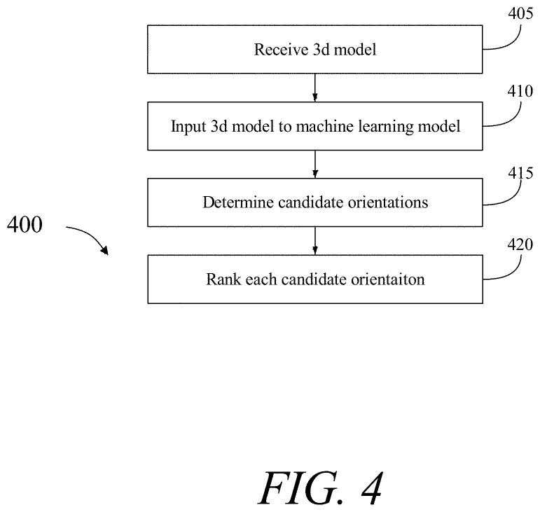

Referring now to FIG. 4, an exemplary method 400 of selection of manufacturing orientation is illustrated. At step 405, computing device may receive a computer model representative of a part for manufacture. Computing device may include any computing device, including for example with reference to FIGS. 1-3 and 5. computer model may include any computer model described in this disclosure, including for example with reference to FIGS. 1-3. Part may include any part described in this disclosure, including for example with reference to FIGS. 1-3.

With continued reference to FIG. 4, at step 410, computing device may input computer model to a machine learning model. Machine learning model may include any machine learning model described in this disclosure, including for example with reference to FIGS. 1-3.

With continued reference to FIG. 4, at step 415, computing device may determine a plurality of candidate orientations as a function of machine learning model and computer model. Plurality of candidate orientations may include any orientations described in this disclosure, including for example with reference to FIGS. 1-3.

With continued reference to FIG. 4, at step 420, computing device may rank each candidate orientation of plurality of candidate orientations as a function of machine learning model and computer model. In some embodiments, computing device may rank each candidate operation orientation according to manufacturing time. In some embodiments, computing device may rank candidate operation orientation according to completeness of manufacture. In some embodiments, ranking each candidate orientation may include a learning to rank process.

Still referring to FIG. 4, in some embodiments, method 400 additionally may include receiving training data, where the training data correlates at least a manufacturing metric to candidate orientation for a plurality of sample parts, inputting the training data to a machine learning algorithm, and training the machine learning model as a function of the machine learning algorithm and the training data. In some cases, method 400 additionally may include inputting a sample computer model representing a sample part of plurality of sample parts to a computer aided manufacturing (CAM) resource a first toolpath as a function of the sample computer model, the CAM resource, and a first candidate orientation a second toolpath as a function of the sample computer model, the CAM resource, and a second candidate orientation, determining at least a first manufacturing metric as a function of the first toolpath and at least a second manufacturing metric as a function of the second toolpath, generating the training data, where the training data correlates the first candidate orientation to the at least a first manufacturing metric and the second candidate orientation to the at least a second manufacturing metric. In some cases, at least one of first toolpath and second toolpath are machining toolpaths.

Still referring to FIG. 4, in some embodiments, method 400 may additionally include receiving an element of part data and selecting machine learning model as a function of the element of part data or computer model. In some cases, part data may include part material.

Still referring to FIG. 4, in some embodiments, receiving computer model may additionally include receiving the computer model from a user device. In some versions, method 400 may additionally include inputting computer model to a computer aided manufacturing (CAM) resource, generating a toolpath as a function of the computer model, the CAM resource, and a candidate orientation of plurality of candidate orientations, and transmitting the toolpath to a tool.

It is to be noted that any one or more of the aspects and embodiments described herein may be conveniently implemented using one or more machines (e.g., one or more computing devices that are utilized as a user computing device for an electronic document, one or more server devices, such as a document server, etc.) programmed according to the teachings of the present specification, as will be apparent to those of ordinary skill in the computer art. Appropriate software coding can readily be prepared by skilled programmers based on the teachings of the present disclosure, as will be apparent to those of ordinary skill in the software art. Aspects and implementations discussed above employing software and/or software modules may also include appropriate hardware for assisting in the implementation of the machine executable instructions of the software and/or software module.

Such software may be a computer program product that employs a machine-readable storage medium. A machine-readable storage medium may be any medium that is capable of storing and/or encoding a sequence of instructions for execution by a machine (e.g., a computing device) and that causes the machine to perform any one of the methodologies and/or embodiments described herein. Examples of a machine-readable storage medium include, but are not limited to, a magnetic disk, an optical disc (e.g., CD, CD-R, DVD, DVD-R, etc.), a magneto-optical disk, a read-only memory “ROM” device, a random-access memory “RAM” device, a magnetic card, an optical card, a solid-state memory device, an EPROM, an EEPROM, and any combinations thereof. A machine-readable medium, as used herein, is intended to include a single medium as well as a collection of physically separate media, such as, for example, a collection of compact discs or one or more hard disk drives in combination with a computer memory. As used herein, a machine-readable storage medium does not include transitory forms of signal transmission.

Such software may also include information (e.g., data) carried as a data signal on a data carrier, such as a carrier wave. For example, machine-executable information may be included as a data-carrying signal embodied in a data carrier in which the signal encodes a sequence of instruction, or portion thereof, for execution by a machine (e.g., a computing device) and any related information (e.g., data structures and data) that causes the machine to perform any one of the methodologies and/or embodiments described herein.

Examples of a computing device include, but are not limited to, an electronic book reading device, a computer workstation, a terminal computer, a server computer, a handheld device (e.g., a tablet computer, a smartphone, etc.), a web appliance, a network router, a network switch, a network bridge, any machine capable of executing a sequence of instructions that specify an action to be taken by that machine, and any combinations thereof. In one example, a computing device may include and/or be included in a kiosk.

FIG. 5 shows a diagrammatic representation of one embodiment of a computing device in the exemplary form of a computer system 500 within which a set of instructions for causing a control system to perform any one or more of the aspects and/or methodologies of the present disclosure may be executed. It is also contemplated that multiple computing devices may be utilized to implement a specially configured set of instructions for causing one or more of the devices to perform any one or more of the aspects and/or methodologies of the present disclosure. Computer system 500 includes a processor 504 and a memory 508 that communicate with each other, and with other components, via a bus 512. Bus 512 may include any of several types of bus structures including, but not limited to, a memory bus, a memory controller, a peripheral bus, a local bus, and any combinations thereof, using any of a variety of bus architectures.

Processor 504 may include any suitable processor, such as without limitation a processor incorporating logical circuitry for performing arithmetic and logical operations, such as an arithmetic and logic unit (ALU), which may be regulated with a state machine and directed by operational inputs from memory and/or sensors; processor 504 may be organized according to Von Neumann and/or Harvard architecture as a non-limiting example. Processor 504 may include, incorporate, and/or be incorporated in, without limitation, a microcontroller, microprocessor, digital signal processor (DSP), Field Programmable Gate Array (FPGA), Complex Programmable Logic Device (CPLD), Graphical Processing Unit (GPU), general purpose GPU, Tensor Processing Unit (TPU), analog or mixed signal processor, Trusted Platform Module (TPM), a floating-point unit (FPU), and/or system on a chip (SoC).

Memory 508 may include various components (e.g., machine-readable media) including, but not limited to, a random-access memory component, a read only component, and any combinations thereof. In one example, a basic input/output system 516 (BIOS), including basic routines that help to transfer information between elements within computer system 500, such as during start-up, may be stored in memory 508. Memory 508 may also include (e.g., stored on one or more machine-readable media) instructions (e.g., software) 520 embodying any one or more of the aspects and/or methodologies of the present disclosure. In another example, memory 508 may further include any number of program modules including, but not limited to, an operating system, one or more application programs, other program modules, program data, and any combinations thereof.

Computer system 500 may also include a storage device 524. Examples of a storage device (e.g., storage device 524) include, but are not limited to, a hard disk drive, a magnetic disk drive, an optical disc drive in combination with an optical medium, a solid-state memory device, and any combinations thereof. Storage device 524 may be connected to bus 512 by an appropriate interface (not shown). Example interfaces include, but are not limited to, SCSI, advanced technology attachment (ATA), serial ATA, universal serial bus (USB), IEEE 1394 (FIREWIRE), and any combinations thereof. In one example, storage device 524 (or one or more components thereof) may be removably interfaced with computer system 500 (e.g., via an external port connector (not shown)). Particularly, storage device 524 and an associated machine-readable medium 528 may provide nonvolatile and/or volatile storage of machine-readable instructions, data structures, program modules, and/or other data for computer system 500. In one example, software 520 may reside, completely or partially, within machine-readable medium 528. In another example, software 520 may reside, completely or partially, within processor 504.

Computer system 500 may also include an input device 532. In one example, a user of computer system 500 may enter commands and/or other information into computer system 500 via input device 532. Examples of an input device 532 include, but are not limited to, an alpha-numeric input device (e.g., a keyboard), a pointing device, a joystick, a gamepad, an audio input device (e.g., a microphone, a voice response system, etc.), a cursor control device (e.g., a mouse), a touchpad, an optical scanner, a video capture device (e.g., a still camera, a video camera), a touchscreen, and any combinations thereof. Input device 532 may be interfaced to bus 512 via any of a variety of interfaces (not shown) including, but not limited to, a serial interface, a parallel interface, a game port, a USB interface, a FIREWIRE interface, a direct interface to bus 512, and any combinations thereof. Input device 532 may include a touch screen interface that may be a part of or separate from display 536, discussed further below. Input device 532 may be utilized as a user selection device for selecting one or more graphical representations in a graphical interface as described above.

A user may also input commands and/or other information to computer system 500 via storage device 524 (e.g., a removable disk drive, a flash drive, etc.) and/or network interface device 540. A network interface device, such as network interface device 540, may be utilized for connecting computer system 500 to one or more of a variety of networks, such as network 544, and one or more remote devices 548 connected thereto. Examples of a network interface device include, but are not limited to, a network interface card (e.g., a mobile network interface card, a LAN card), a modem, and any combination thereof. Examples of a network include, but are not limited to, a wide area network (e.g., the Internet, an enterprise network), a local area network (e.g., a network associated with an office, a building, a campus or other relatively small geographic space), a telephone network, a data network associated with a telephone/voice provider (e.g., a mobile communications provider data and/or voice network), a direct connection between two computing devices, and any combinations thereof. A network, such as network 544, may employ a wired and/or a wireless mode of communication. In general, any network topology may be used. Information (e.g., data, software 520, etc.) may be communicated to and/or from computer system 500 via network interface device 540.

Computer system 500 may further include a video display adapter 552 for communicating a displayable image to a display device, such as display device 536. Examples of a display device include, but are not limited to, a liquid crystal display (LCD), a cathode ray tube (CRT), a plasma display, a light emitting diode (LED) display, and any combinations thereof. Display adapter 552 and display device 536 may be utilized in combination with processor 504 to provide graphical representations of aspects of the present disclosure. In addition to a display device, computer system 500 may include one or more other peripheral output devices including, but not limited to, an audio speaker, a printer, and any combinations thereof. Such peripheral output devices may be connected to bus 512 via a peripheral interface 556. Examples of a peripheral interface include, but are not limited to, a serial port, a USB connection, a FIREWIRE connection, a parallel connection, and any combinations thereof.

The foregoing has been a detailed description of illustrative embodiments of the invention. Various modifications and additions can be made without departing from the spirit and scope of this invention. Features of each of the various embodiments described above may be combined with features of other described embodiments as appropriate in order to provide a multiplicity of feature combinations in associated new embodiments. Furthermore, while the foregoing describes a number of separate embodiments, what has been described herein is merely illustrative of the application of the principles of the present invention. Additionally, although particular methods herein may be illustrated and/or described as being performed in a specific order, the ordering is highly variable within ordinary skill to achieve methods, systems, and software according to the present disclosure. Accordingly, this description is meant to be taken only by way of example, and not to otherwise limit the scope of this invention.

Exemplary embodiments have been disclosed above and illustrated in the accompanying drawings. It will be understood by those skilled in the art that various changes, omissions and additions may be made to that which is specifically disclosed herein without departing from the spirit and scope of the present invention.

What is claimed is:

1. A method of manufacturing orientation selection using machine learning, the method comprising:
receiving, using a computing device, a computer model representative of a part for manufacture;
inputting, using the computing device, the computer model to a machine learning model;
determining, using the computing device, a plurality of candidate orientations as a function of the machine learning model and the computer model; and
ranking, using the computing device, each candidate orientation of the plurality of candidate orientations as a function of the machine learning model and the computer model.

2. The method of claim 1, further comprising:
selecting, using the computing device, a candidate orientation from the plurality of candidate orientations.

3. The method of claim 1, further comprising:
ranking, using the computing device, each candidate operation orientation according to manufacturing time.

4. The method of claim 1, further comprising:
ranking, using the computing device, each candidate operation orientation according to completeness of manufacture.

5. The method of claim 1, further comprising:
receiving, using the computing device, training data, wherein the training data correlates at least a manufacturing metric to candidate orientation for a plurality of sample parts;
inputting, using the computing device, the training data to a machine learning algorithm; and
training, using the computing device, the machine learning model as a function of the machine learning algorithm and the training data.

6. The method of claim 5, further comprising:
inputting, using the computing device, a sample computer model representing a sample part of the plurality of sample parts to a computer aided manufacturing (CAM) resource;
generating, using the computing device, a first toolpath as a function of the sample computer model, the CAM resource, and a first candidate orientation;
generating, using the computing device, a second toolpath as a function of the sample computer model, the CAM resource, and a second candidate orientation;
determining, using the computing device, at least a first manufacturing metric as a function of the first toolpath and at least a second manufacturing metric as a function of the second toolpath;
generating, using the computing device, the training data, wherein the training data correlates the first candidate orientation to the at least a first manufacturing metric and the second candidate orientation to the at least a second manufacturing metric.

7. The method of claim 6, wherein the first toolpath and the second toolpath are machining toolpaths.

8. The method of claim 1, wherein ranking each candidate orientation comprises a learning to rank process.

9. The method of claim 1, further comprising:
receiving, using the computing device, element of part data; and
selecting, using the computing device, the machine learning model as a function of the element of part data or the computer model.

10. The method of claim 9, wherein the part data includes part material.

11. The method of claim 1, wherein receiving the computer model further comprises receiving, using the computing device, the computer model from a user device; and the method further comprises:
inputting, using the computing device, the computer model to a computer aided manufacturing (CAM) resource;
generating, using the computing device, a toolpath as a function of the computer model, the CAM resource, and a candidate orientation of the plurality of candidate orientations; and
transmitting, using the computing device, the toolpath to a tool.

12. A system for manufacturing orientation selection using machine learning, the system comprising a computing device configured to:
receive a computer model representative of a part for manufacture;
input the computer model to a machine learning model;
determine a plurality of candidate orientations as a function of the machine learning model and the computer model; and
rank each candidate orientation of the plurality of candidate orientations as a function of the machine learning model and the computer model.

13. The system of claim 12, wherein the computing device is further configured to select a candidate orientation from the plurality of candidate orientations.

14. The system of claim 12, wherein the computing device is further configured to:
rank each candidate operation orientation according to manufacturing time.

15. The system of claim 12, wherein the computing device is further configured to:
rank each candidate operation orientation according to completeness of manufacture.

16. The system of claim 12, wherein the computing device is further configured to:
receive training data, wherein the training data correlates at least a manufacturing metric to candidate orientation for a plurality of sample parts;
input the training data to a machine learning algorithm; and
train the machine learning model as a function of the machine learning algorithm and the training data.

17. The system of claim 16, wherein the computing device is further configured to:
input a sample computer model representing a sample part of the plurality of sample parts to a computer aided manufacturing (CAM) resource;
generate a first toolpath as a function of the sample computer model, the CAM resource, and a first candidate orientation;
generate a second toolpath as a function of the sample computer model, the CAM resource, and a second candidate orientation;
determine at least a first manufacturing metric as a function of the first toolpath and at least a second manufacturing metric as a function of the second toolpath;
generate the training data, wherein the training data correlates the first candidate orientation to the at least a first manufacturing metric and the second candidate orientation to the at least a second manufacturing metric.

18. The system of claim 17, wherein the first toolpath and the second toolpath are machining toolpaths.

19. The system of claim 12, wherein ranking each candidate orientation comprises a learning to rank process.

20. The system of claim 12, wherein the computing device is further configured to:
receive an element of part data; and
select the machine learning model as a function of the element of part data or the computer model.

21. The system of claim 20, wherein the part data includes part material.

22. The system of claim 12, wherein receiving the computer model further comprises receiving, using the computing device, the computer model from a user device; and the computing device is further configured to:
input the computer model to a computer aided manufacturing (CAM) resource;
generate a toolpath as a function of the computer model, the CAM resource, and a candidate orientation of the plurality of candidate orientations; and
transmit the toolpath to a tool.
